(19) United States
(12) Patent Application Publication
(10) Pub. No.: US 2002/0124219 A1
(43) Pub. Date: Sep. 5, 2002

(54) Pseudo random signal producing circuit

(76) Inventor: Reiko Kuroki, Kawasaki-shi (JP)

Correspondence Address: KATTEN MUCHIN ZAVIS ROSENMAN, 575 MADISON AVENUE, NEW YORK, NY, 10022-2585, US

(21) Appl. No.: 10/090,874

(22) Filed: Mar. 5, 2002

(30) Foreign Application Priority Data
Mar. 5, 2001 (JP) 60593/2001

(51) Int. Cl. G01R 31/28; G06F 11/00; G11C 29/00

(52) U.S. Cl. 714/739; 714/718

(57) ABSTRACT

A pseudo random signal producing circuit includes a generator 110 for generating a first pseudo random signal having a bit width a (a being an integer not smaller than 1), a generator 120 for generating a second pseudo random signal having a bit width b (b being an integer not smaller than 1 and different from a), a matrix calculator 130 for carrying out matrix calculation upon the first and the second pseudo random signals to produce a calculation result signal having a bit width (a*b), an N-bit shift register 200 responsive to the calculation result signal having the bit width (a*b) for producing an output pseudo random signal having a bit width N (N being a divisor of (a*b)), and a frequency-division clock generator 300 for driving a pseudo random data generator 100.

### BACKGROUND OF THE INVENTION

This invention relates to a pseudo random signal producing circuit mounted in a self-test circuit incorporated into or built in a semiconductor integrated circuit having a target module to be tested.

A pseudo random signal producing circuit mounted in a self-test circuit serves to verify a macro block (functional block) as a target module. The macro block is a physical layer (PHY) and has two modes in which data widths are 20 bits and 10 bits, respectively. The self-test circuit transmits to the PHY a reference pattern including a random data signal and verifies that the PHY produces an expected value. In order to detect errors by the self-test circuit for both of the two modes of the PHY, the random data signal as the reference pattern produced by the self-test circuit must also have two modes of 20-bit and 10-bit widths.

Thus, the target module to be tested often requires test data having a variable test pattern which can be selected from a plurality of different patterns (N=N1, N2, N3, . . . ). For example, the test data have a bit width N which can be selected from N1, N2, N3, . . . In order to meet such requirement, Japanese Unexamined Patent Publication (A) No. H07-98995 discloses a method in which a linear feedback shift register (hereinafter abbreviated to LFSR) produces a maximum random data signal having a maximum bit width Nmax. By the use of a switch, a FF (flip-flop) or FFs corresponding to a difference between the maximum bit width Nmax and a desired bit width N currently required is disconnected or isolated to obtain a desired random data signal having the desired bit width N.

As well known to those skilled in the art, the bit width N is equivalent in meaning to “N bits in width”.

In the above-mentioned method, however, the desired random data signal is variable in pattern length. The desired bit width N is variable between the maximum value Nmax and the minimum value Nmin. The range of variation, i.e., the difference between the maximum bit width Nmax and the minimum bit width Nmin corresponds to the difference in pattern length on the order of an exponential function. Specifically, the maximum pattern length is as large as (2^{Nmax}−1)/(2^{Nmin}−1) times the minimum pattern length. Thus, the self-test circuit has a serious problem that error correction depends upon the pattern length and can not evenly been carried out.

On the other hand, Japanese Unexamined Patent Publication (A) No. H05-288808 discloses another method in which a first LFSR produces a first random data signal having data bits equal in number to the difference (Nmax−Nmin) between the maximum bit width Nmax and the minimum bit width Nmin while a second LFSR produces a second random data signal having data bits equal in number to the minimum bit width Nmin. The first random data signal, having the (Nmax−Nmin) data bits and produced by the first LFSR, is compressed by the difference (Nmax−N) between the maximum bit width Nmax and the desired bit width N and is thereafter combined to the second random data signal having the data bits equal in number to Nmin and produced by the second LFSR. Thus, a desired random data signal is obtained as N=Nmin+((Nmax−Nmin)−(Nmax−N)). In this method also, the desired random data signal is variable in pattern length as described in conjunction with JP H07-98995 A except in a special condition. In the special condition, the first and the second LFSRs produce random data signals equal in bit width, i.e., in number of bits to each other and therefore cross-correlation is established therebetween. In addition, an error miss ratio is increased as a result of the compression.

In order to avoid the above-mentioned serious problem as the self-test circuit yet with the same circuit structure, control circuits for producing enable signals to control generation of the random data signals in the self-test circuit must be individually designed in correspondence to the numbers of input terminals so as to evenly perform error detection without repetition of the random data signals (in view of reduction in testing time).

In either of the above-mentioned two Japanese publications, the circuit scale becomes inevitably large in proportion to the maximum number of bits of the desired random data signal. Therefore, limitation is imposed upon reduction of the circuit area on a chip. Specifically, the circuit area can not be smaller than the area required by the FFs equal in number to the bits of the maximum bit width of the random data signal.

Thus, the advantages of the reduced area and the generality allowing selection of the number of input terminals of a plurality of test modules with the same circuit structure are lessened by a wide difference in the number of the patterns in view of the error detection.

### SUMMARY OF THE INVENTION

It is therefore an object of this invention to provide a pseudo random signal producing circuit which can remove the above-mentioned defects.

According to this invention, there is provided a pseudo random signal producing circuit comprising:

a first generator for generating a first pseudo random signal having a bit width a (a being an integer not smaller than 1);

a second generator for generating a second pseudo random signal having a bit width b (b being an integer not smaller than 1 and different from a),

a matrix calculator for executing a matrix calculation upon an (a,b)-type matrix with the first and the second pseudo random signals as a row and a column, respectively, to produce a calculation result signal having a bit width (a*b); and

a bit width adjusting circuit responsive to the calculation result signal having the bit width (a*b) for producing an output pseudo random signal having a bit width N (N being a divisor of (a*b)).

According to this invention, there is also provided a pseudo random signal producing circuit comprising:

a first generator for generating a first pseudo random signal having a bit width a (a being an integer not smaller than 1);

a second generator for generating a second pseudo random signal having a bit width b (b being an integer not smaller than 1 and different from a);

a matrix calculator for executing a matrix calculation upon an (a,b)-type matrix with the first and the second pseudo random signals as a row and a column, respectively, to produce a calculation result signal having a bit width (a*b); and

an N-bit shift register responsive to the calculation result signal having the bit width (a*b) for producing an output pseudo random signal having a bit width N (N being a divisor of (a*b)).

According to this invention, there is also provided a pseudo random signal producing circuit comprising:

a first generator for generating a first pseudo random signal having a bit width a (a being an integer not smaller than 1);

a second generator for generating a second pseudo random signal having a bit width b (b being an integer not smaller than 1 and different from a);

a matrix calculator for performing a matrix calculation upon the first and the second pseudo random signals to produce a calculation result signal having a bit width (a*b); and

a bit width adjusting circuit responsive to the calculation result signal having the bit width (a*b) for producing an output pseudo random signal having a bit width N (N being a divisor of (a*b)).

According to this invention, there is also provided a pseudo random signal producing circuit comprising:

a first generator for generating a first pseudo random signal having a bit width a (a being an integer not smaller than 1);

a second generator for generating a second pseudo random signal having a bit width b (b being an integer not smaller than 1 and different from a);

a first matrix calculator for performing a matrix calculation upon an (a,b)-type matrix with the first and the second pseudo random signals as a row and a column, respectively, to produce a first calculation result signal having a bit width (a*b);

a third generator for generating a third pseudo random signal having a bit width c (c being an integer not smaller than 1 and different from a and b);

a second matrix calculator for performing a matrix calculation upon a (a*b,c)-type matrix with the first calculation result signal and the third pseudo random signal as a row and a column, respectively, to produce a second calculation result signal having a bit width (a*b*c); and

a bit width adjusting circuit responsive to the second calculation result signal having the bit width (a*b*c) for producing an output pseudo random signal having a bit width N (N being a divisor of (a*b*c)).

According to this invention, there is also provided a pseudo random signal producing circuit comprising:

a first generator for generating a first pseudo random signal having a bit width a (a being an integer not smaller than 1);

a second generator for generating a second pseudo random signal having a bit width b (b being an integer not smaller than 1 and different from a);

a first matrix calculator for performing a matrix calculation upon an (a,b)-type matrix with the first and the second pseudo random signals as a row and a column, respectively, to produce a first calculation result signal having a bit width (a*b);

a third generator for generating a third pseudo random signal having a bit width c (c being an integer not smaller than 1 and different from a and b);

a second matrix calculator for performing a matrix calculation upon a (a*b,c)-type matrix with the first calculation result signal and the third pseudo random signal as a row and a column, respectively, to produce a second calculation result signal having a bit width (a*b*c); and

an N-bit shift register responsive to the second calculation result signal having the bit width (a*b*c) for producing an output pseudo random signal having a bit width N (N being a divisor of (a*b*c)).

According to this invention, there is also provided a pseudo random signal producing circuit comprising:

a first generator for generating a first pseudo random signal having a bit width a (a being an integer not smaller than 1);

a second generator for generating a second pseudo random signal having a bit width b (b being an integer not smaller than 1 and different from a);

a first matrix calculator for performing a matrix calculation upon the first and the second pseudo random signals to produce a first calculation result signal having a bit width (a*b);

a third generator for generating a third pseudo random signal having a bit width c (c being an integer not smaller than 1 and different from a and b);

a second matrix calculator for performing a matrix calculation upon the first calculation result signal and the third pseudo random signal to produce a second calculation result signal having a bit width (a*b*c); and

a bit width adjusting circuit responsive to the second calculation result signal having the bit width (a*b*c) for producing an output pseudo random signal having a bit width N (N being a divisor of (a*b*c)).

Thus, according to this invention, the matrix calculator performs the matrix calculation upon the first pseudo random signal having a small bit width and the second pseudo random signal having a small bit width to produce the calculation result signal having a large bit width. The calculation result signal having the large bit width is divided into the output pseudo random signal having the bit width N. Thus, the pseudo random signal producing circuit for a self-test is given a function of adjusting the bit width.

### BRIEF DESCRIPTION OF THE DRAWING

FIG. 1 is a block diagram of a pseudo random signal producing circuit according to a first embodiment of this invention;

FIG. 2 shows an a-bit M-series generator in the pseudo random signal producing circuit illustrated in FIG. 1;

FIG. 3 shows a b-bit M-series generator in the pseudo random signal producing circuit illustrated in FIG. 1;

FIG. 4 shows a matrix calculator in the pseudo random signal producing circuit illustrated in FIG. 1;

FIG. 5 shows a specific example of the pseudo random signal producing circuit illustrated in FIG. 1;

FIG. 6 is a timing chart for describing an operation of the pseudo random signal producing circuit illustrated in FIG. 1;

FIG. 7 is a timing chart for describing an operation of the circuit illustrated in FIG. 5;

FIG. 8 is a block diagram of a pseudo random signal producing circuit according to a second embodiment of this invention; and

FIG. 9 is a timing chart for describing an operation of the pseudo random signal producing circuit illustrated in FIG. 8.

### DESCRIPTION OF THE PREFERRED EMBODIMENTS

Now, description will be made of a few preferred embodiments of this invention with reference to the drawing.

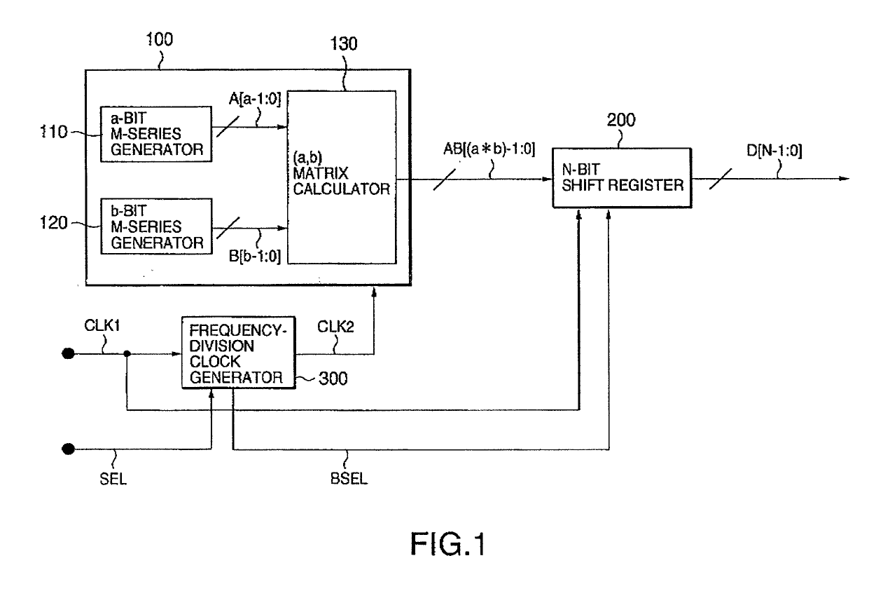

Referring to FIG. 1, a pseudo random signal producing circuit according to a first embodiment of this invention comprises a pseudo random data generator 100, an N-bit shift register 200, and a frequency-division clock generator 300. The pseudo random data generator 100 comprises a matrix calculator 130 and at least two M-series generators. In order that the pseudo random signal producing circuit is adapted to deal with a plurality of desired bit widths (for example, 10-bit and 20-bit widths), the M-series generators produce outputs having bit widths corresponding to different divisors or measures (for example, 5 and 4) of the least common multiple (i.e., 20) of the numbers of bits of the desired bit widths (i.e., 10 and 20). In the illustrated example, the M-series generators comprises an a-bit M-series generator 110 and a b-bit M-series generator 112.

In case where a pseudo random signal having a desired bit width selected from a plurality of different bit widths is required, the pseudo random signal producing circuit exhibits its characteristic. Specifically, the a-bit and the b-bit M-series generators 110 and 120 of the pseudo random data generator 100 produce pseudo random data having bit widths corresponding to different divisors of the least common multiple of the numbers of bits of the pseudo random signals having a plurality of desired bit widths. The a-bit M-series generator 110 produces a-bit pseudo random data or signal A[a-1:0] while the b-bit M-series generator 120 produces b-bit pseudo random data or signal B[b-1:0]. The matrix calculator 130 performs multiplication upon an (a,b)-type matrix with the first and the second pseudo random signals A[a-1:0] and B[b-1:0] as a row and a column, respectively. The matrix calculator 130 produces an output signal having a bit width which is equal in number to the common multiple of the desired bit widths. The output signal of the matrix calculator 130 is divided by the shift register 200 into data having the desired bit widths, respectively.

Herein, A[a-1:0] represents A[0], A[1], . . . , A[a-1]. Likewise, B[b-1:0] represents B[0], B[1], . . . , B[b-1].

The above-mentioned method uses the M-series generators each of which generates a small number of bits corresponding to the divisor. Therefore, a plurality of modes having a plurality of bit widths can be dealt with by the single circuit.

The pseudo random signal producing circuit illustrated in FIG. 1 will be described in detail.

The pseudo random data generator 100 comprises the a-bit M-series generator 110 for producing the a-bit pseudo random signal A[a-1:0], the b-bit M-series generator 120 for producing the b-bit pseudo random signal B[b-1:0], and the matrix calculator 130 for calculating the (a,b)-type matrix. The frequency-division clock generator 300 is supplied with a reference clock signal CLK1 having a first frequency f1 and produces a frequency-division clock signal CLK2 having a second frequency f2. The a-bit and the b-bit M-series generators 110 and 120 are supplied with the frequency-division clock signal CLK2. The matrix calculator 130 for calculating the (a,b)-type matrix is supplied with the a-bit pseudo random signal A[a-1:0] as the output of the a-bit M-series generator 110 and the b-bit pseudo random signal B[b-1:0] as the output of the b-bit M-series generator 120 and produces an output AB[(a*b)-1:0] which is supplied to the N-bit shift register 200.

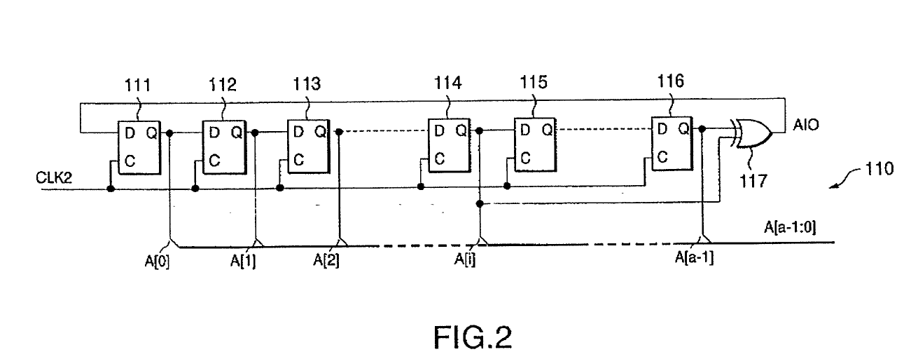

Referring to FIG. 2, the a-bit M-series generator 110 comprises a plurality of flip-flops (hereinafter abbreviated to FFs) 111 to 116, a in number, and an exclusive OR gate (hereinafter abbreviated to EXOR) 117.

The FFs 111 to 116 are arranged in the form of a shift register in which an output of each FF is connected in series to an input of another FF at a next stage. The final-stage FF 116 produces the output A[a-1] which is supplied to the EXOR 117. Together with the output A[a-1], the EXOR 117 is supplied with the output A[i] extracted from a middle tap position of the shift register, The value i in A[i] is calculated by a primitive polynomial (for the primitive polynomial, see the coding theory). The EXOR 117 produces an output AIO which is fed back to an input of the first-stage FF 111. Furthermore, the outputs A[0] through A[a-1] are extracted from tap positions between every adjacent ones of the FFs 111 through 116 and the EXOR 117 to obtain random data having a bits.

It is assumed here that an output bit width N is selected from N1, N2, and N3 in response to a selection signal SEL (FIG. 1) having a value a supplied from the outside and that the bit width a is a divisor of N′ where N′ is the least common multiple of N1, N2, and N3. Then, the bit width a satisfy:

N′mod(a)=0 and N′mod(N)=0 (1)

where mod(a) represents a residue or module resulting from division by a.

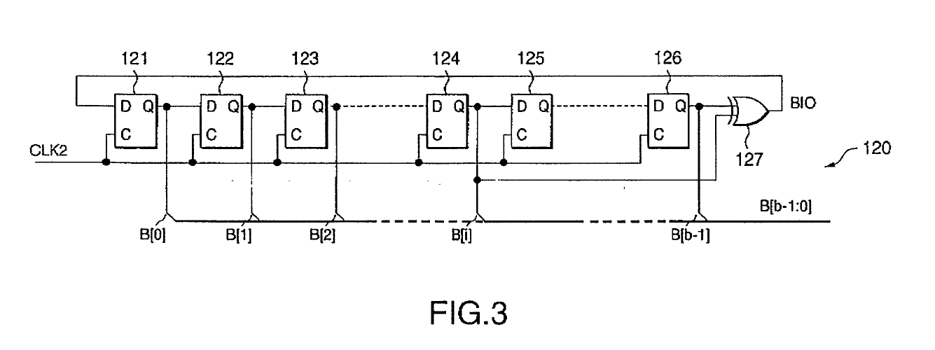

Referring to FIG. 3, the b-bit M-series generator 120 comprises a plurality of FFs 121 to 126, b in number, and an EXOR 127.

Like the a-bit M-series generator 110, the FFs are arranged in the form of a shift register. Together with the output B[b-1], the EXOR 127 is supplied with the output B[0]. The value j in B[j] is calculated by a primitive polynomial according to the coding theory. The EXOR 127 produces an output BIO which is fed back to an input of the first-stage FF121. Furthermore, the outputs B[0] through B[a-1] are extracted from tap positions between every adjacent ones of the FFs 121 through 126 and the EXOR 127 to obtain random data having b bits.

It is assumed here that an output bit width N is selected from N1, N2, and N3 in response to a selection signal SEL (FIG. 1) having a value α supplied from the outside and that the bit width b is a divisor of N′ where N′ is the least common multiple of N1, N2, and N3. Then, the bit width b satisfy:

N′mod(b)=0 and N′mod(N)=0 (2)

Preferably, the values a and b to be selected are prime numbers in order to keep the linear complexity.

Furthermore, consideration will be made of a fault detection rate. Assuming that the self-test circuit requires a pattern length L, the M-series generator 110 produces a pattern length La given by:

La=2^{a}−1

On the other hand, the M-series generator 120 produces a pattern length Lb given by:

Lb=2^{b}−1

The pseudo random data generator 100 produces a pattern length L′. Then, a and b satisfying L′L will be considered. Since L′ is the least common multiple of La and Lb, a and b must not be equal to each other so as to avoid a minimum pattern length, i.e., L′=La=Lb.

That is, a and b satisfy:

a≠b (3)

Then, the pattern length L′ is given by:

L′=La*Lb

Thus, by selecting a and b not equal to each other, the maximum pattern length can be achieved with the two M-series generators 110 and 120.

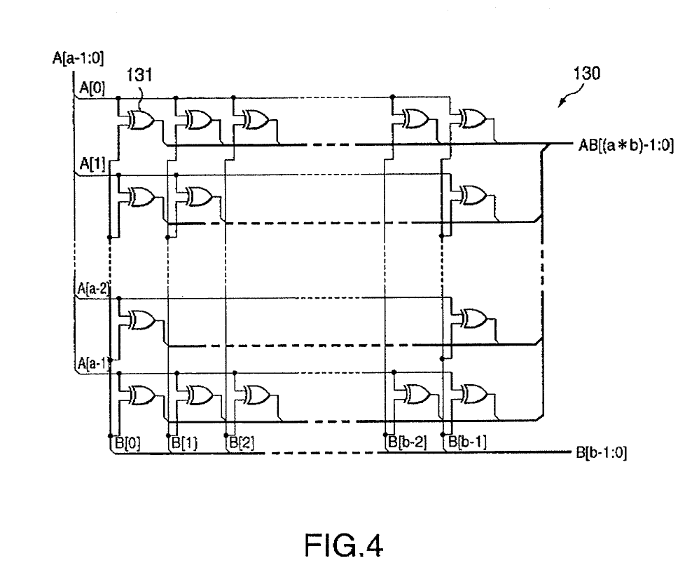

The pseudo random data of a bits produced by the a-bit M-series generator 110 are used as a (a,1)-type matrix. On the other hand, the pseudo random data of b bits produced by the b-bit M-series generator 120 are used as a (1,b)-type matrix. These two matrices are supplied to the matrix calculator 130 illustrated in FIG. 4 and combined by an EXOR 131 into an (a,b)-type matrix by multiplying the respective components. Specifically, a component (a′,b′) is a product, i.e., EXOR of a component (a′,1) in the a-bit pseudo random data as the (a,1)-type matrix and a component (b′,1) in the b-bit pseudo random data as the (b,1)-type matrix. In order to obtain the products of the respective components, a plurality of EXORs, a*b in number, are arranged.

By taking the components in the (a,b)-type matrix, a*b-bit data AB[(a*b)-1:0] are produced.

It is assumed here that the output bit width N is selected from N1, N2, and N3 in response to the selection signal SEL (FIG. 1) having the value α. Then, the bit width a*b of AB[(a*b)-1:0] satisfies:

(a*b)mod(N)=0 (N=N1, N2, N3, . . . ) (4)

because a*b is the least common multiple of N1, N2, N3, . . .

As illustrated in FIG. 1, the N-bit shift register 200 is supplied with the data AB[(a*b)-1:0] produced by the pseudo random data generator 100 at a preceding stage, a data selection signal BSEL (for the N-bit shift register 200,) produced by the frequency-division clock generator 300, and the reference clock signal CLK1 and produces N-bit pseudo random data D[N-1:0] as an output. The selection signal SEL is given the value α. The N-bit shift register 200 shifts the data AB[(a*b)-1:0] having the bit width a*b by every N bits in synchronism with the reference clock signal CLK1 having the first frequency f1 to produce data having the bit width N.

It is assumed here that the bit width N is selected from N1, N2, N3, . . . in response to the selection signal SEL given the value α. Then, the value α given to the selection signal SEL from the outside satisfies the relationship given by:

α=(a*b)/N (N=N1, N2, N3, . . . ) (5)

As illustrated in FIG. 1, the frequency-division clock generator 300 is supplied with the reference clock signal CLK1 having the first frequency f1 and the selection signal SEL for selecting the desired bit width N. The frequency-division clock generator 300 produces the frequency-division clock signal CLK2 having the second frequency f2 obtained by frequency-dividing the reference clock signal CLK1 having the first frequency f1 in response to the value α of the selection signal SEL, and the data selection signal BSEL (for the N-bit shift register 200,) obtained by converting the selection signal SEL. The frequency-division clock signal CLK2 and the data selection signal BSEL are supplied to the pseudo random data generator 100 and the N-bit shift register 300, respectively.

If the selection signal SEL for selecting the desired bit width N is given the value α; the second frequency f2 of the frequency-division clock signal CLK2 is determined by:

f2=f1/α

Herein, let the variables used in the foregoing be given specific values. For example, the desired bit width is selected from 10 bits and 20 bits. Then, the least common multiple of these bit numbers is:

N′=20.

From the above equations (1) and (2):

N′mod(a)=20mod(a)=0

N′mod(b)=20mod(b)=0

a and b satisfying these equations are derived under the conditions of the equations (3) and (4) as follows:

a=5

b=4

Therefore, from the equation 5), the value α given to the selection signal SEL is calculated by:

α=(a*b)/N=(5*4)/10=2

where the desired bit width N is 10 bits, and:

α=(a*b)/N=(5*4)/20=1

where the desired bit width N is 20 bits:

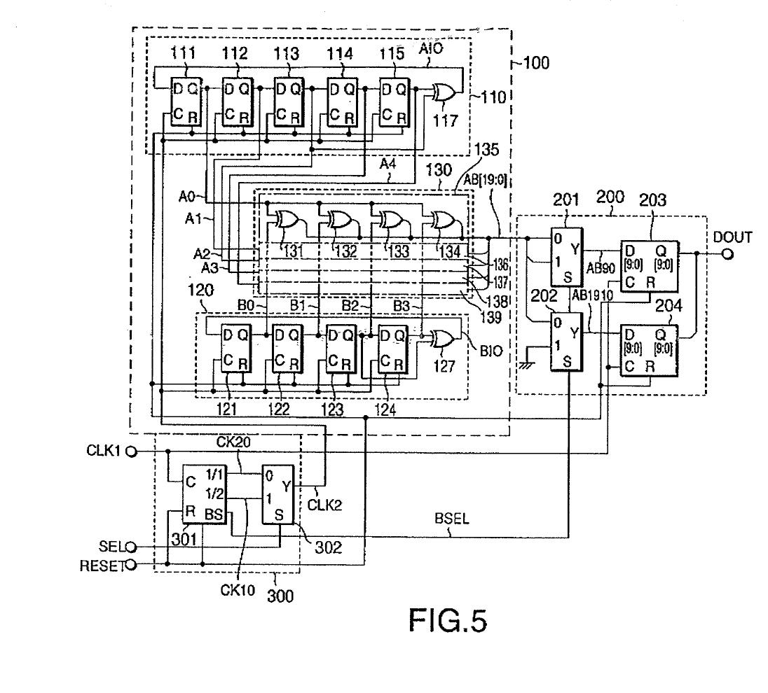

Using the values thus obtained, an actual circuit is implemented as illustrated in FIG. 5.

Referring to FIG. 5, the pseudo random signal producing circuit comprises the frequency-division clock generator 300 supplied with the input reference clock signal CLK1, an input reset signal RESET, and the selection signal SEL for producing the data selection signal BSEL, the pseudo random data generator 100 supplied with the frequency division clock signal CLK2 and the input reset signal RESET for producing random generation data PDATA, and the 20-bit shift register 200 supplied with the input reference clock signal CLK, the input reset signal RESET, the data selection signal BSEL, and the random generation data PDATA for producing random output data DOUT of 20 bits.

The pseudo random data generator 100 comprises a 5-bit M-series generator 110, a 4-bit M-series generator 120, and a matrix calculator 130 for calculating a (4,5)-type matrix.

The 5-bit M-series generator 110 comprises a plurality of FFs 111 through 115, 5 in number, and an EXOR 117.

The FF 111 is supplied with the frequency-division clock signal CLK2 at a clock input port C, the input reset signal RESET at a reset input port R, and the data AIO produced by the EXOR 117 at a data input port D and produces data A0 from an output port Q.

Likewise, the FF112 is supplied with the frequency-division clock signal CLK2 at a clock input port C, the input reset signal RESET at a reset input port R, and the data A0 at a data input port D and produces data A1 from an output port Q.

The FF113 is supplied with the frequency-division clock signal CLK2 at a clock input port C, the input reset signal RESET at a reset input port R, and the data A1 at a data input port D and produces data A2 from an output port Q.

The FF114 is supplied with the frequency-division clock signal CLK2 at a clock input port C, the input reset signal RESET at a reset input port R, and the data A2 at a data input port D and produces data A3 from an output port Q.

The FF115 is supplied with the frequency-division clock signal CLK2 at a clock input port C, the input reset signal RESET at a reset input port R, and the data A3 at a data input port D and produces data A4 from an output port Q.

The EXOR 117 is supplied with the data A2 from the FF 113 and the data A4 from the FF 115 and produces the data AOI.

The 4-bit M series generator 120 comprises a plurality of FFs 121 through 124, 4 in number, and an EXOR 127.

The FF 121 is supplied with the frequency-division clock signal CLK2 at a clock input port C, the input reset signal RESET at a reset input port R, and data BIO produced by the EXOR 127 at a data input port D and produces data B0 from an output port Q.

The FF 122 is supplied with the frequency-division clock signal CLK2 at a clock input port C, the input reset signal RESET at a reset input port R, and the data B0 at a data input port D and produces data B1 from an output port Q.

The FF 123 is supplied with the frequency-division clock signal CLK2 at a clock input port C, the input reset signal RESET at a reset input port R, and the data B1 at a data input port D and produces data B2 from an output port Q.

The FF 124 is supplied with the frequency-division clock signal CLK2 at a clock input port C, the input reset signal RESET at a reset input port R, and the data B2 at a data input port D and produces data B3 from an output port Q.

The EXOR 127 is supplied with the data B2 from the FF 123 and the data B3 from the FF 124 and produces the data BOI.

The matrix calculator 130 for calculating a (4,5)-type matrix comprises a plurality of 4-bit data calculators 135 through 139, 4 in number.

The 4-bit data calculator 135 comprises a plurality of EXORs 131 to 134, 4 in number. Each of the EXORs 131 to 134 has one input supplied with the data A0 from the 5-bit M-series generator 110. The EXOR 131 has the other input supplied with the data B0 from the 4-bit M-series generator 120 and produces an output AB[0]. The EXOR 132 has the other input supplied with the data B1 and produces an output AB[1]. The EXOR 133 has the other input supplied with the data B2 and produces an output AB[2]. The EXOR 134 has the other input supplied with the data B3 and produces an output AB[3].

Similarly, the 4-bit data calculator 136 comprising four EXORs is supplied with the data A1 from the 5-bit M-series generator 110 and the data B[3:0] from the 4-bit M-series generator 120 and produces data AB[7:4].

The 4-bit data calculator 137 is supplied with the data A2 from the 5-bit M-series generator 110 and the data B[3:0] from the 4-bit M-series generator 120 and produces data AB[11:8].

The 4-bit data calculator 138 is supplied with the data A3 from the 5-bit M-series generator 110 and the data B[3:0] from the 4-bit M-series generator 120 and produces data AB[15:12].

The 4-bit data calculator 139 is supplied with the data A4 from the 5-bit M-series generator 110 and the data B[3:0] from the 4-bit M-series generator 120 and produces data AB[19:16].

The 20-bit shift register 200 comprises a lower 10 bit selector 201, an upper 10 bit selector 202, a lower 10 bit FF 203, and an upper 10 bit FF 204.

The lower 10 bit selector 201 is supplied with the lower 10 bits AB[9:0] and the upper 10 bits AB[19:10] of the random data AB[19:0]. In response to the data selection signal BSEL, the lower 10 bit selector 201 selects the lower 10 bits AB[9:0] and produces selected lower data AB90 as an output.

The upper 10 bit selector 202 is supplied with the upper 10 bits AB[19:10] of the random data AB[19:0] and a ground level, i.e., “0”. In response to the data selection signal BSEL, the upper 10 bit selector 202 selects the upper 10 bits AB[19:10] and produces selected upper data AB1910 as an output.

The lower 10 bit FF 203 is supplied with the reference clock signal CLK1 at a clock input port, the input reset signal RESET at a reset input port, and the lower selected data D90 at a data input port and produces random data DOUT[9:0] from an output port Q.

The upper 10 bit FF 204 is supplied with the reference clock signal CLK1 at a clock input port, the input reset signal RESET at a reset input port, and the upper selected data D1910 at a data input port and produces random data DOUT[19:10] from an output port Q.

The frequency-division clock generating circuit 300 comprises a frequency divider 301 and a selector 302.

The frequency divider 301 is initialized by the input reset signal RESET. The frequency divider 301 is supplied with the reference clock signal CLK1 and produces an output clock signal CK20 having a cycle equal to that of the reference clock signal CLK1, a frequency-division clock signal CK10 obtained by frequency-dividing the input reference clock signal CLK1 at a leading edge thereof, and a data selection signal BSEL having an output level reverse to that of the frequency-division clock signal CK10 except that the output level becomes a low level when the input reset signal RESET is supplied. The selector 302 is supplied with the output clock signal CK20 and the frequency-division clock signal CK10. In response to the input selection signal SEL, the selector 302 selects and produces the frequency-division clock signal CLK2.

Now, the operation of the embodiment in FIG. 1 will be described.

Referring to FIG. 2, the data A[a-1:0] produced by the a-bit M-series generator 110 are pseudo random data calculated by a characteristic polynomial:

A(X)=X^{a}+X^{(a-1)}+1

Referring to FIG. 3, the data B[b-1:0] produced by the b-bit M-series generator 120 are pseudo random data calculated by a characteristic polynomial:

B(X)=X^{b}+X^{(b-1)}+1

The pseudo random data A[a-1:0] and B[b-1:0] are used as an (a,1)-type matrix and a (1,b)-type matrix, respectively. The two pseudo random data are supplied to the (a,b)-type matrix calculator 130 in FIG. 1 where the EXORs performs matrix multiplication to obtain products as an (a,b)-type matrix. The components in the (a,b)-type matrix are distributed in parallel as data of a*b bits to produce pseudo random data AB[(a*b)-1:0] as an output.

The pseudo random data AB[(a*b)-1:0] thus produced are synchronized with the frequency-division clock signal CLK2 having the second frequency f2 obtained by frequency-dividing the reference clock signal CLK1 having the first frequency f1 into 1/α at the frequency-division clock generator 300. It is, noted here that α is the value given to the selection signal SEL for selecting the desired bit width N and represented by the equation (5).

The pseudo random data AB[(a*b)-1:0] are supplied to the N-bit shift register 200 at a next stage and successively outputted by every N bits at a time in synchronism with the reference clock signal CLK1 having the first frequency f1.

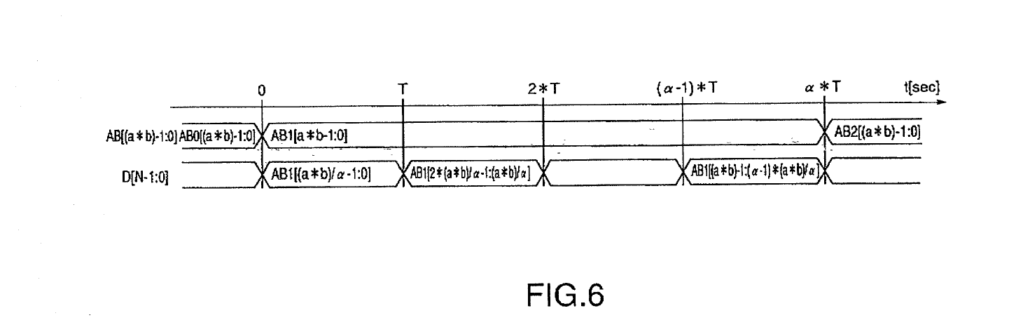

Referring to FIG. 6, the N-bit shift register 200 is supplied with an input AB1[(a*b)-1:0] and produces an output D[N-1:0].

At first, the first frequency f1 of the reference clock signal CLK1 has a cycle defined by a time T determined by:

f1/=1/T

During a first period between the time instants 0 and T, the N-bit shift register 200 synchronized with the first frequency f1 outputs upper N bits of AB1[(a*b)-1:0]. Thus, the relationship between the output D[N-1:0] and the input AB1[(a*b)-1:0] is given by:

D[N-1:0]=AB1[N-1:0]=AB1[(a*b)/α-1:0]

During a next period between the time instants T and 2*T, the relationship is given by:

D[N-1:0]=AB1[2*N-1:N]=AB1[2*(a*b)/α-1:2*(a*b)]

As described in the foregoing, the input data AB[(a*b)-1:0] supplied to the N-bit shift register 200 are synchronized with the second frequency f2 of the frequency-division clock signal CLK2 If:

f2=1/T′

the second frequency f2 of the frequency-division clock signal CLK2 produced by the frequency-division clock generator 300 and the first frequency f1 of the reference clock signal CLK1 have the relationship given by:

f2=f1/α

Since the equation (5) is:

α=(a*b)/N

the value α given to the selection signal SEL is represented by:

T′=α*T

If the input AB1[(a*b)/α-1:0] is supplied, the data produced by the N-bit shift register 200 at the time instant t (0<t<α*T) are given by:

D[N-1:0]=AB[(t/T−tmod(T))*(a*b)-1:(t/T−tmod)(T)-1)*(a*b)]

Thus, the N-bit shift register 200 divides the input data AB1[(a*b)-1:0] into segments of N bits during the time period up to the time instant T′ and produces all the segments.

Hereinafter, description will be made of a specific example where actual values used in FIG. 5 are supplied.

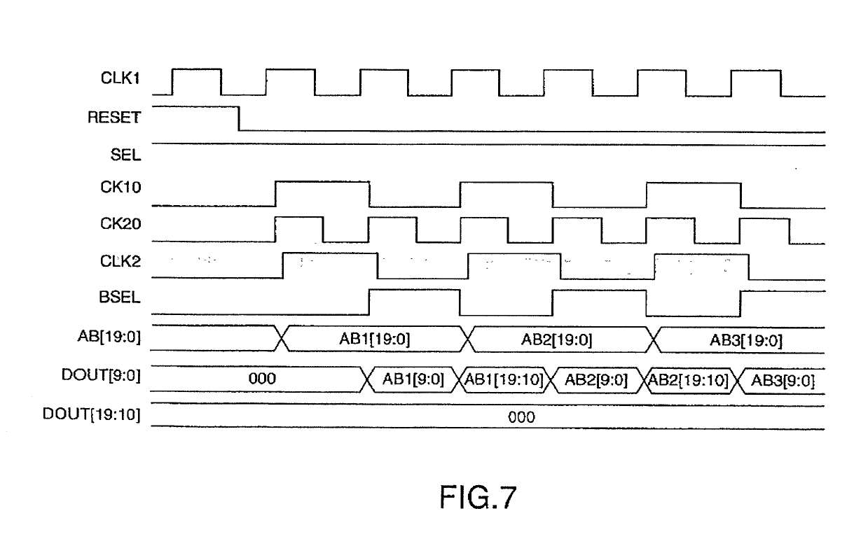

Referring to FIG. 7, the operation of the circuit illustrated in FIG. 5 will be described.

In response to the input reset signal RESET, the pseudo random data generator 100 is initialized into an initial value and the frequency-division clock generator 300 puts all of the outputs into a low level. The 20-bit shift register 200 initializes the lower 10 bit FF 203 and the upper 10 bit FF 204 into 0.

It is assumed here that the selection signal SEL is given a value α=2. In this event, the selector 302 selects, as the frequency-division clock signal CLK2 having the second frequency f2, the frequency-division clock signal CK10 obtained by frequency-dividing the reference clock signal CLK1 having the frequency f1 into half. The data selection signal BSEL has an output level reverse to that of the frequency-division clock signal CK10 as described above.

In response, the 20-bit shift register 200 operates in the following manner. When the data selection signal BSEL has a high level, the selector 201 selects, as selected data, the lower 10 bits AB[9:0] of the output AB[19:0] of the pseudo random data generator 100 and the lower 10 bit FF203 holds the selected data. On the other hand, when the data selection signal BSEL has a low level, the selector 202 selects, as selected data, the upper 10 bits AB[19:10] and the upper 10 bit FF 204 holds the selected data. Thus, the lower 10 bits and the upper 10 bits are alternately selected and 10-bit output data DOUT are produced.

The input data AB[19:0] supplied at that time are the pseudo random data generated by the pseudo random data generator 100. The pseudo random data have 20 bits obtained by the matrix calculator 130 where the respective bits of the data A0 to A4 produced by the 5-bit M-series generator 110 and the data B0 to B3 produced by the four-bit M-series generator 120 are combined as described above.

Herein, the effect of this embodiment will be described.

The number P of patterns of the random data having n bits in an M series can be represented by 2ⁿ−1 except the case where all bits are equal to zero. It is assumed that the M-series generator produces the random data of 20 bits. Then, the pattern length L is given by:

L=2²⁰−1

If the M-series generator produces the random data of 10 bits:

L=2¹⁰−1

Thus, in case where the random signal is produced for a predetermined time duration and the self-test circuit detects errors, a wide gap of (2²⁰−1)/(2¹⁰−1) in pattern length is present between the 20-bit M-series generator and the 10-bit M-series generator. However, according to the method of this invention, the 20-bit data and the 10-bit data are produced by the use of the 4-bit M-series generator and the 5-bit M-series generator. In this event, the pattern length L at the 20 bits is given by:

L=(2⁵−1)*(2⁴−1)

At the 10 bits:

L=((2⁴−1)*(2⁵−1)−1)*2

Thus, the gap is as small as twice.

This means that, in case where the random signal is produced for a predetermined time duration, it is possible to suppress the unevenness in error detection ratio in the self-test circuit due to the gap in the number of patterns.

In view of the circuit scale, the following effect is obtained.

If a mode of producing random data having a plurality of (two or more) kinds of bit widths, an existing random data generating portion requires a plurality of FFs, equal in number to the bits of the maximum bit width. On the other hand, according to this invention, the outputs of the two pseudo random signal generators have bit widths smaller than a desired bit width. These outputs are taken as the row and the column to be subjected to matrix calculation. Thus, the desired bit width is obtained. With this structure, the number of FFs can be reduced and the circuit scale is reduced.

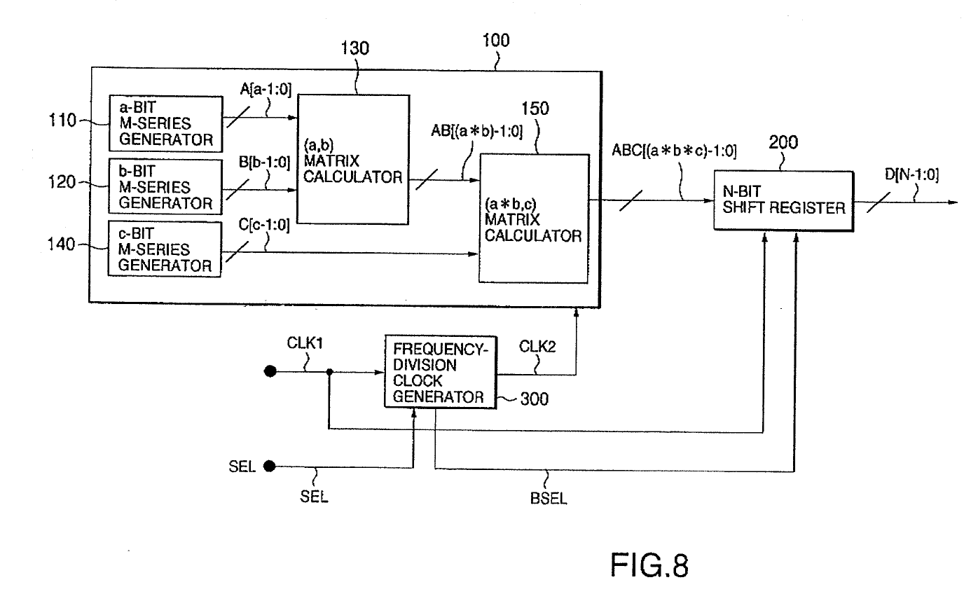

Referring to FIG. 8, a pseudo random signal producing circuit according to a second embodiment of this invention is similar in basic structure to the first embodiment described above. In the second embodiment, a greater number of desired bit widths can be dealt with.

In FIG. 8, an algorithm different from that in FIG. 1 resides in an internal structure of the pseudo random data generator 100. The pseudo random data generator 100 in FIG. 8 further comprises a c-bit M-series generator 140 for producing pseudo random data having a bit width c corresponding to another divisor c used in producing random data to be supplied to the N-bit shift register 200. Thus, a greater number of bits can be dealt with.

At first, the (a,b)-type matrix calculator 130 is supplied with the matrix A[a-1:0] of a (a,1) type produced by the a-bit M-series generator 110 and the matrix B[b-1:0] of a (1,b) type produced by the b-bit M series generator 120 and obtains output data AB[(a*b)-1:0].

Herein, by additionally providing the c-bit M-series generator 140, the output AB[(a*b)-1:0] of the (a,b)-type matrix calculator 130 is used as the (a*b,1)-type matrix. The (1,c)-type matrix C[c-1:0] produced by the c-bit M-series generator 140 is supplied to the (a*b,c)-type matrix calculator 150 to produce output data ABC[(a*b*c)-1:0] having the bit width a*b*c*.

Herein, the bit width N may have any desired value as far as the following condition is met:

(a*b*c)mod(N)=0

The value α given to the selection signal SEL for selecting the bit width N is given by:

α=(a*b*c)/N

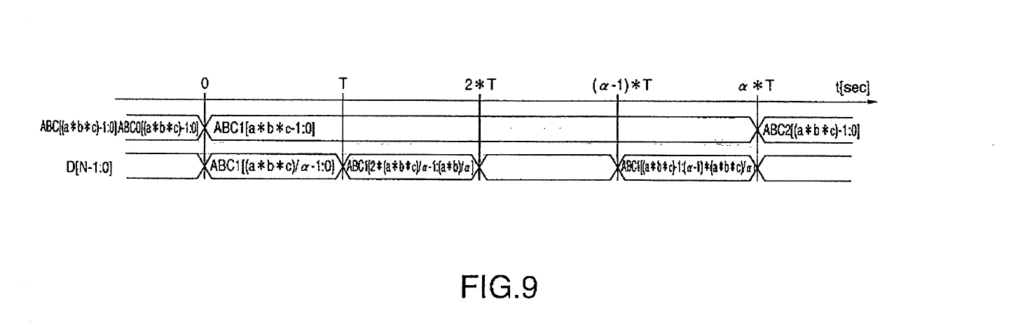

Referring to FIG. 9, the circuit having the structure in FIG. 8 is operated in the following manner. The pseudo random data generator 100 produces the data ABC[(a*b*c)-1:0] to be supplied to the N-bit shift register 200. The frequency f1 of the reference clock signal has a cycle defined by a time T determined by:

f1=1/T

Then, the data produced at the time instant t (0<t<α*T) is given by:

D[N-1:0]=ABC[(t/T−tmod(T))*(a*b*c)−1:(t/T−tmod(T)-1)*(a*b*c)]

Thus, a greater number of bits can be dealt with by providing the pseudo random data generator 100 with an additional M series generator corresponding to an additional divisor in the similar manner.

Next referring to FIG. 8, a pseudo random signal producing circuit according to a third embodiment of this invention will be described.

The pseudo random signal producing circuit according to the third embodiment is similar in basic structure to the second embodiment. In the third embodiment, the pattern length is increased.

In FIG. 8, the M-series generator 140 of the pseudo random data generator 100 produces an output having the bit width c. In the second embodiment, the divisors are increased so as to deal with a greater number of bit widths. In this embodiment, the divisors are used as a factor for increasing the pattern length.

The pattern length in FIG. 1 is given by:

L=(2^{a}−1)*(2^{b}−1)

On the other hand, the pattern length L in FIG. 8 is given by:

L=(2^{a}−1)*(1^{c}−1)

Thus, this value is as great as (2^{c}−1) times the value in case where the a-bit M-series generator 110 and the b-bit M-series generator 120 are used. This brings about the increase in linearity complex, i.e., the increase in randomness.

As described above, according to this invention, the outputs of at least two pseudo random signal generators having bit widths smaller than the desired bit width are used as a row and a column for matrix calculation. By the matrix calculation, the desired bit width is obtained. Therefore, the number of FFs required is reduced and the circuit scale can be miniaturized.

What is claimed is:

1. A pseudo random signal producing circuit comprising:
a first generator for generating a first pseudo random signal having a bit width a (a being an integer not smaller than 1);
a second generator for generating a second pseudo random signal having a bit width b (b being an integer not smaller than 1 and different from a);
a matrix calculator for executing a matrix calculation [operation] upon an (a,b)-type matrix with the first and the second pseudo random signals as a row and a column, respectively, to produce a calculation result signal having a bit width (a*b); and
a bit width adjusting circuit responsive to the calculation result signal having the bit width (a*b) for producing an output pseudo random signal having a bit width N (N being a divisor of (a*b)).

2. A pseudo random signal producing circuit comprising:
a first generator for generating a first pseudo random signal having a bit width a (a being an integer not smaller than 1);
a second generator for generating a second pseudo random signal having a bit width b (b being an integer not smaller than 1 and different from a);
a matrix calculator for executing a matrix calculation upon an (a,b)-type matrix with the first and the second pseudo random signals as a row and a column, respectively, to produce a calculation result signal having a bit width (a*b); and
an N-bit shift register responsive to the calculation result signal having the bit width (a*b) for producing an output pseudo random signal having a bit width N (N being a divisor of (a*b)).

3. A pseudo random signal producing circuit comprising:
a first generator for generating a first pseudo random signal having a bit width a (a being an integer not smaller than 1);
a second generator for generating a second pseudo random signal having a bit width b (b being an integer not smaller than 1 and different from a);
a matrix calculator for performing a matrix calculation upon the first and the second pseudo random signals to produce a calculation result signal having a bit width (a*b); and
a bit width adjusting circuit responsive to the calculation result signal having the bit width (a*b) for producing an output pseudo random signal having a bit width N (N being a divisor of (a*b)).

4. A pseudo random signal producing circuit comprising:
a first generator for generating a first pseudo random signal having a bit width a (a being an integer not smaller than 1);
a second generator for generating a second pseudo random signal having a bit width b (b being an integer not smaller than 1 and different from a);
a first matrix calculator for performing a matrix calculation upon an (a,b)-type matrix with the first and the second pseudo random signals as a row and a column, respectively, to produce a first calculation result signal having a bit width (a*b);
a third generator for generating a third pseudo random signal having a bit width c (c being an integer not smaller than 1 and different from a and b);
a second matrix calculator for performing a matrix calculation upon a (a*b,c)-type matrix with the first calculation result signal and the third pseudo random signal as a row and a column, respectively, to produce a second calculation result signal having a bit width (a*b*c); and
a bit width adjusting circuit responsive to the second calculation result signal having the bit width (a*b*c) for producing an output pseudo random signal having a bit width N (N being a divisor of (a*b*c)).

5. A pseudo random signal producing circuit comprising:
a first generator for generating a first pseudo random signal having a bit width a (a being an integer not smaller than 1);
a second generator for generating a second pseudo random signal having a bit width b (b being an integer not smaller than 1 and different from a);
a first matrix calculator for performing a matrix calculation upon an (a,b)-type matrix with the first and the second pseudo random signals as a row and a column, respectively, to produce a first calculation result signal having a bit width (a*b);
a third generator for generating a third pseudo random signal having a bit width c (c being an integer not smaller than 1 and different from a and b);
a second matrix calculator for performing a matrix calculation upon a (a*b,c)-type matrix with the first calculation result signal and the third pseudo random signal as a row and a column, respectively, to produce a second calculation result signal having a bit width (a*b*c); and
an N-bit shift register responsive to the second calculation result signal having the bit width (a*b*c) for producing an output pseudo random signal having a bit width N (N being a divisor of (a*b*c)).

6. A pseudo random signal producing circuit comprising:
a first generator for generating a first pseudo random signal having a bit width a (a being an integer not smaller than 1);
a second generator for generating a second pseudo random signal having a bit width b (b being an integer not smaller than 1 and different from a);
a first matrix calculator for performing a matrix calculation upon the first and the second pseudo random signals to produce a first calculation result signal having a bit width (a*b);
a third generator for generating a third pseudo random signal having a bit width c (c being an integer not smaller than 1 and different from a and b);
a second matrix calculator (150) for performing a matrix calculation upon the first calculation result signal and the third pseudo random signal to produce a second calculation result signal having a bit width (a*b*c); and
a bit width adjusting circuit responsive to the second calculation result signal having the bit width (a*b*c) for producing an output pseudo random signal having a bit width N (N being a divisor of (a*b*c)).
